(19) United States
(12) Patent Application Publication
(10) Pub. No.: US 2005/0110533 A1
(43) Pub. Date: May 26, 2005

(54) Power up circuit

(75) Inventor: Jong Ho Son, Seoul (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/752,275

(22) Filed: Jan. 6, 2004

(30) Foreign Application Priority Data
Nov. 25, 2003 (KR) 2003-83900

(51) Int. Cl. H03L 7/00

(52) U.S. Cl. 327/143

(57) ABSTRACT

Provided is a power up circuit comprising: a reference voltage generator arranged in a semiconductor memory device to generate an internal voltage source of the semiconductor memory device; a first current path control unit that is turned on in accordance with an output of the reference voltage generator to increase a potential of a first node to a voltage of an external voltage source; a second current path control unit that is turned on in accordance with the output of the reference voltage generator to sink the voltage of the first node down to a ground level; and a driving unit for generating a power up signal in accordance with the voltage of the first node.

### BACKGROUND

1. Field of the Invention

The present invention relates to a power up circuit for determining an initial state of a chip in a semiconductor memory device when an external voltage is applied thereto and, more particularly, to a power up circuit capable of reducing a chip area as well as increasing immunity against changes of a temperature and a process.

2. Discussion of Related Art

In recent years, a power up circuit is used in most of the memory devices such as DRAM so as to sense the increase of an initial external voltage and set an initial operating state in the DRAM.

The power up circuit of the prior art is significantly affected by changes of an external temperature and a process and a layout area in the chip is also large. In particular, the power up circuit is extremely sensitive to changes of the external temperature and process, so that a point of time when a signal for notifying the required power up state is enabled greatly varies, thereby causing a problem in operating the chip.

Hereinafter, the power up circuit in accordance with the prior art will be described with reference to FIG. 1 and FIG. 2.

The power up circuit in accordance with the prior art largely consists of a resistance divider 10, a series of PMOS transistors 20, a series of NMOS transistors 30, and a capacitor 40.

A total resistance value is changed in accordance with on/off of switches connected to each of the resistors of the resistance divider 10, and an external voltage is divided by these resistors, and when the external voltage is low, a signal aa outputted from the resistance divider also becomes low, which is input to the NMOS transistors of the series of NMOS transistors 30 to be turned off. As a result, PMOS transistors of the series of PMOS transistors 20 are turned on, so that a current supplied through the series of PMOS transistors makes a potential of a node n0 to be higher. Therefore, a final output signal pwrup of the power up circuit, which has passed through inverters INV1 to INV3, maintains the low state.

In contrast, when the external voltage starts to increase, the level of the signal aa becomes higher, so that the NMOS transistors of the series of NMOS transistors 30 are turned on, thereby making the current flowing through the series of PMOS transistors 20 to be sunk to the ground through the NMOS transistors. As a result, the level of the node n0 maintains the low level, so that the final output signal pwrup of the power up circuit, which is an output of the inverter INV3, becomes high.

The problem of the prior art is that the resistance divider relative to the external voltage is extremely sensitive to changes of the temperature and process. To detail this, as shown in FIG. 2, a variable width of the power up signal due to the changes of temperature and process is 0.71V (1.32V˜2.03V). The point of time when the power up signal pwrup is enabled varies within a large range, thereby causing an error when the chip is set to an initial state.

### SUMMARY OF THE INVENTION

The present invention is directed to a power up circuit for determining an initial state of a chip in a semiconductor memory device when an external voltage is applied thereto. And the purpose of the present invention is to provide a power up circuit capable of reducing a chip area while increasing the immunity against temperature and process changes.

The power up circuit of the present invention to accomplish the above purpose comprises: a reference voltage generator arranged in a semiconductor memory device to generate an internal voltage source of the semiconductor memory device; a first current path control unit that is turned on in accordance with an output of the reference voltage generator to increase a potential of a first node to a voltage of an external voltage source; a second current path control unit that is turned on in accordance with the output of the reference voltage generator to sink the voltage of the first node down to a ground level; and a driving unit for generating a power up signal in accordance with the voltage of the first node.

### BRIEF DESCRIPTION OF THE DRAWINGS

FIG. 1 shows a power up circuit in accordance with the prior art.

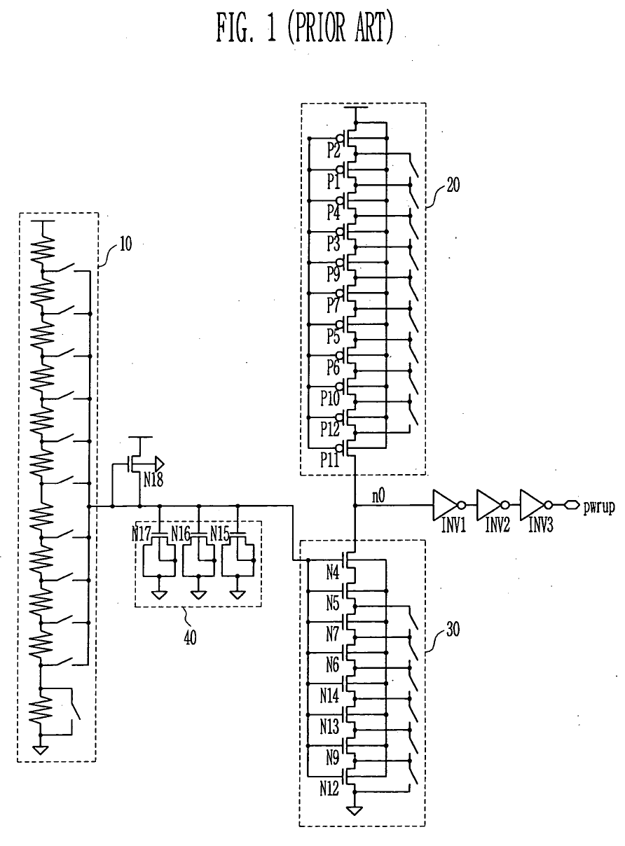

FIG. 2 is a graph for showing the result simulated by using the power up circuit in accordance with the prior art.

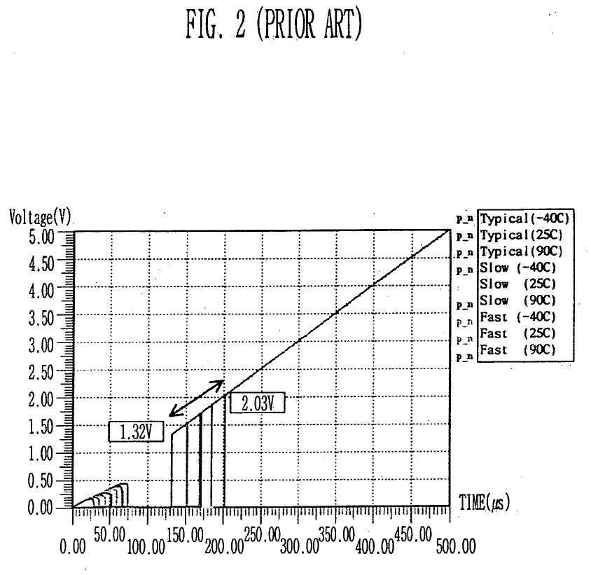

FIG. 3 shows a circuit of a reference voltage generator.

FIG. 4 shows a power up circuit in accordance with a first embodiment of the present invention.

FIG. 5 is a graph for showing the result simulated by using a power up circuit in accordance with a first embodiment of the present invention.

### DETAILED DESCRIPTION OF PREFERRED EMBODIMENTS

Hereinafter, an embodiment of the present invention will be described with reference to the accompanying drawings.

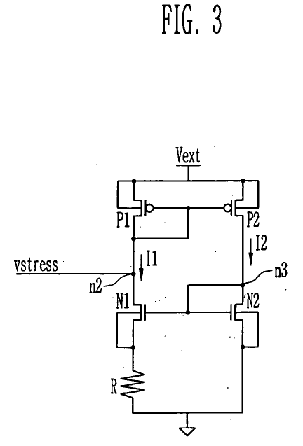

FIG. 3 shows a circuit of a reference voltage generator employed in a power up circuit in accordance with the present invention.

The reference voltage generator of FIG. 3 is constructed in a chip for the purpose of generating an internal voltage in a semiconductor memory device.

In the present invention, an output of the reference voltage generator is used as an input of an NMOS transistor of the power up circuit. The reference voltage generator is described below in detail.

The reference voltage generator comprises first and second PMOS transistors P1 and P2 connected as a current-mirror type between a second node n2 and an external voltage source Vext and between a third node n3 and the external voltage source Vext, respectively. A first NMOS transistor N1 which has a gate connected to the third node n3, is connected between the ground and the second node n2 that is an output of the reference voltage generator. A second NMOS transistor N2, which has a gate connected to the second node n2, is connected between the ground and the third node n3.

Since the NMOS transistors N1 and N2 are the current mirror type, currents I1 and I2 flowing through each of the NMOS transistors become equal when channel widths and channel lengths of the NMOS transistors are the same.

Vgsn1 of the NMOS transistor N1 can be expressed as the equation 1 below.

$${V}_{th} + \sqrt{\frac{2 {I}_{1}}{{μ}_{n} {{C}_{ox} ( W / L )}_{1}}} \qquad Equation 1$$

Vgsn2 of the NMOS transistor N2 can be expressed as the equation 2 below.

$${V}_{th} + \sqrt{\frac{2 {I}_{2}}{{μ}_{n} {{C}_{ox} ( W / L )}_{2}}} \qquad Equation 2$$

In the equation 2, Vgs2=Vgs1+I₁R, thereby obtaining the equation 3 below.

$${V}_{th} + \sqrt{\frac{2 {I}_{1}}{{μ}_{n} {{C}_{ox} ( W / L )}_{1}}} + {I}_{1} R = {V}_{th} + \sqrt{\frac{2 {I}_{2}}{{μ}_{n} {{C}_{ox} ( W / L )}_{2}}} \qquad Equation 3$$

In addition, I1=I2 can be obtained by the current mirror effect of the PMOS transistors P1 and P2, thereby obtaining the equation 4 below.

$${I}_{1} = {I}_{2} = {\frac{2}{{R}^{2} {μ}_{n} {C}_{ox}} [ \frac{1}{\sqrt{{( W / L )}_{2}}} - \frac{1}{\sqrt{{( W / L )}_{1}}} ]}^{2} \qquad Equation 4$$

Therefore, the output voltage of the reference voltage generator Vstress, namely, Vgsp1 of the PMOS transistor P1 can be expressed as the equation 5 below.

$${V}_{stress} = {V}_{ext} - \{ {V}_{th} + \frac{2}{R {μ}_{n} {C}_{ox} \sqrt{{( W / L )}_{2}}} [ \frac{1}{{( W / L )}_{2}} - \frac{1}{{( W / L )}_{1}} ] \} \qquad Equation 5$$

As can be seen from the equation 5, when the temperature becomes higher, the threshold voltage Vth and mobility μₙ are decreased, so that the output of the reference voltage generator Vstress has a constant rate relative to the external voltage. Therefore, the reference voltage can be generated, which is less affected by the changes of temperature and process.

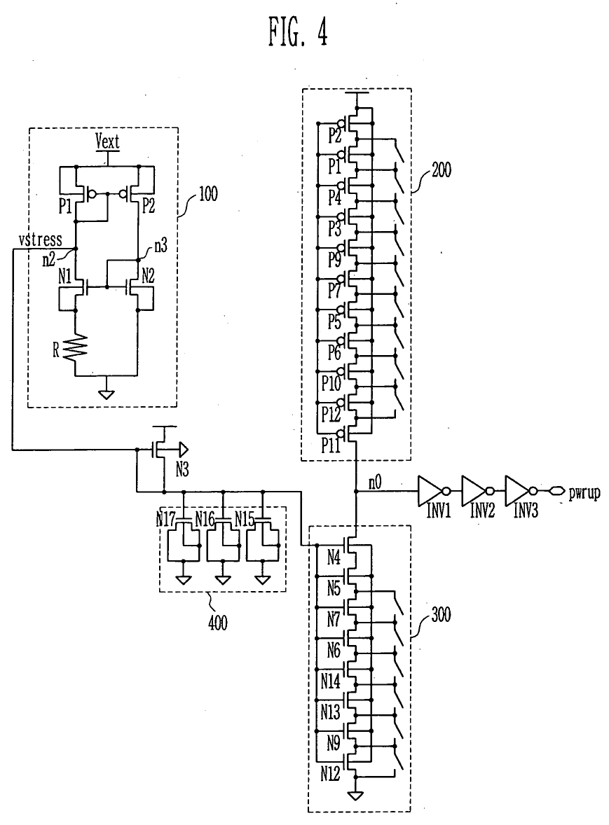

FIG. 4 shows a power up circuit in accordance with the present invention employing the reference voltage generator shown in FIG. 3.

The power up circuit in accordance with the present invention largely consists of a reference voltage generator 100, a series of PMOS transistors 200, a series of NMOS transistors 300, and a capacitor 400.

The configuration except the reference voltage generator 100 is the same as that of the prior art.

When the power is supplied to the reference voltage generator 100, it generates a constant reference voltage Vstress as is described in FIG. 3.

When an external voltage Vext is low, the signal Vstress outputted from the reference voltage generator also becomes low, which is inputted to the series of NMOS transistors 300 to be turned off. As a result, the series of PMOS transistors 200 are then turned on, so that currents flowing through the series of PMOS transistors 200 make a potential of the node n0 to be higher. Therefore, a signal that has passed through the inverters INV1 to INV3 that act as a driving unit, namely, a final output signal of the power up circuit pwrup maintains the low state.

In contrast, when the external voltage Vext starts to increase, the level of the signal Vstress outputted from the reference voltage generator becomes higher, so that the NMOS transistor N3 is turned on to charge the capacitor 400 to the external voltage Vext. Since the series of NMOS transistors 300 are turned on by the charged voltage in the capacitor 400, the currents flowing through the series of PMOS transistors 200 are sunk to the ground through the series of NMOS transistors 300. As a result, the, level of the node n0 maintains the low state, thereby making an output of the inverter INV3, namely, the final output signal pwrup of the power up circuit to be high.

The series of PMOS transistors 200 consist of a plurality of PMOS transistors serially connected between the external voltage Vext and the node n0, and a plurality of switches for shorting out each of the drains and sources thereof, wherein a resistance divider may be used instead of the switches.

The series of NMOS transistors 300 consist of a plurality of NMOS transistors serially connected between the node n0 and the ground, and a plurality of switches for shorting out each of the drains and sources thereof.

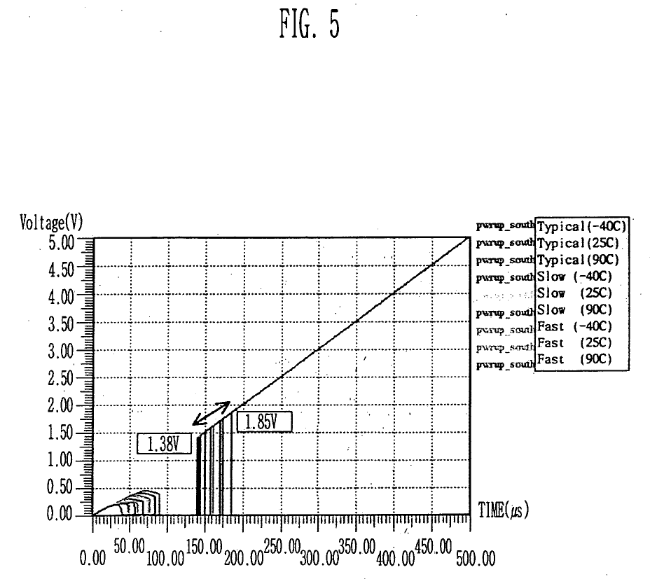

FIG. 5 is a graph for showing a result simulated by using a power up circuit in accordance with a first embodiment of the present invention, and it can be seen that a variable width of the power up signal is 0.40V (1.86V˜1.46V). FIG. 5 shows the result simulated by a condition including changes of temperature (−40° C., 25° C., 90° C.) and process (typical, slow, fast conditions). As shown in FIG. 5, the variable width of the power up signal is significantly less than that of the prior art.

As mentioned above, according to the present invention, the variation of the power up signal due to changes of temperature and process can be minimized, and there is no resistance divider that takes a large area in the chip, so that the layout area can be reduced by 30%.

1. A power up circuit, comprising:
a reference voltage generator arranged in a semiconductor memory device to generate an internal voltage source of the semiconductor memory device;
a first current path control unit that is turned on in accordance with an output of the reference voltage generator to increase a potential of a first node to a voltage of an external voltage source;
a second current path control unit that is turned on in accordance with the output of the reference voltage generator to sink the voltage of the first node down to a ground level; and
a driving unit for generating a power up signal in accordance with the voltage of the first node.

2. The power up circuit claimed in 1, wherein the first current path control unit consists of a plurality of PMOS transistors.

3. The power up circuit claimed in 1, wherein the second current path control unit consists of a plurality of NPMOS transistors.

4. The power up circuit claimed in 1, wherein the first current path control unit consists of resistance dividers.

5. The power up circuit claimed in 1, further comprising:
an NMOS transistor that is connected between the external voltage source and the output of the reference voltage generator and turned on in accordance with the output of the reference voltage generator; and
a capacitor connected between the output of the reference voltage generator and the ground.

6. The power up circuit claimed in 1, wherein the reference voltage generator consists of,
first and second PMOS transistors connected between the external voltage source and a second node and between the external voltage source and a third node in a current mirror type, respectively;
a first NMOS transistor connected between the ground and the second node that is an output of the reference voltage source, and has its gate connected to the third node; and
a second NMOS transistor connected between the ground and the third node, and has its gate connected to the second node.

7. The power up circuit claimed in 6, further comprising:
a capacitor connected between the second node and the ground.

8. The power up circuit claimed in 1, wherein the driving unit consists of a plurality of inverters serially connected to one another.
